(19) United States
(12) Patent Application Publication
(10) Pub. No.: US 2017/0353169 A1
(43) Pub. Date: Dec. 7, 2017

(54) SIGNAL PROCESSING APPARATUS AND SIGNAL PROCESSING METHOD

(71) Applicant: YAMAHA CORPORATION, Hamamatsu-shi (JP)

(72) Inventor: Takayuki WATANABE, HAMAMATSU-SHI (JP)

(21) Appl. No.: 15/606,088

(22) Filed: May 26, 2017

(30) Foreign Application Priority Data
Jun. 1, 2016 (JP) 2016-109951

(51) Int. Cl. H03G 3/32; G10H 1/12; G10K 15/12; H04R 29/00

(52) U.S. Cl. CPC H03G 3/32; H04R 29/007; G10H 1/125; G10K 15/12

(57) ABSTRACT

A signal processing apparatus includes: an obtaining portion configured to obtain an impulse response in a semi-open state in which, among a plurality of acoustic feedback systems, at least one acoustic feedback system is open and at least one acoustic feedback system is closed; and a calculating portion configured to calculate a gain correction amount based on the impulse response that the obtaining portion has obtained and to output a calculated gain correction amount.

### CROSS REFERENCE

This Nonprovisional application claims priority under 35 U.S.C. §119(a) on Patent Application No. 2016-109951 filed in Japan on Jun. 1, 2016, the entire contents of which are hereby incorporated by reference.

### BACKGROUND OF THE INVENTION

### 1. Field of the Invention

Some preferred embodiments of the present invention relate to a signal processing apparatus and a signal processing method that are capable of calculating a gain correction amount by analyzing an input signal.

### 2. Description of the Related Art

In facilities such as a concert hall, music of various genres may be performed or a speech such as a lecture may be delivered. Such facilities require various acoustic characteristics (reverberation characteristics, for example). For example, a performance requires comparatively long reverberation while a speech requires comparatively short reverberation.

However, in order to physically change reverberation characteristics in a concert hall, the size of an acoustic space needs to be changed by moving a ceiling, for example, so that very large-scale equipment has been necessary.

Accordingly, a sound field control device disclosed in Japanese Unexamined Patent Application Publication No. H06-284493, for example, performs processing to support a sound field by processing a sound collected by a microphone through an FIR filter to generate a reverberant sound and outputting the reverberant sound from a speaker installed in a concert hall.

However, in such a sound field control device, the sound that has been output from the speaker is collected again by the microphone through the transmission system of an acoustic space and processed by the FIR filter and then is output from the speaker. In other words, the sound field control device includes an acoustic feedback system. Therefore, if acoustic field support is performed, a specific frequency component may increase and howling or coloration may occur.

Accordingly, an acoustic field support device disclosed in Japanese Unexamined Patent Application Publication No. 2012-060333, for example, performs processing to reduce howling or coloration by performing signal processing in which the amplitude characteristics of an impulse response are smoothed.

However, the cause of coloration is not only due to the transmission system of an acoustic space. Coloration includes: coloration that occurs because, due to original standing waves in the acoustic space, specific standing waves remain for a long time in an attenuation process when an impulse is generated in a room; and coloration due to the acoustic feedback of a system. Examples of coloration due to the acoustic feedback of a system includes a case in which, when a sudden sound occurs, the sudden sound is amplified by signal processing and a specific frequency component may increase.

### SUMMARY OF THE INVENTION

In view of the foregoing, preferred embodiments of the present invention are directed to provide a signal processing apparatus and a signal processing method that are capable of reducing both coloration due to the transmission system of an acoustic space and coloration due to signal processing.

A signal processing apparatus according to a preferred embodiment of the present invention includes: an obtaining portion configured to obtain an impulse response in a semi-open state in which, among a plurality of acoustic feedback systems, at least one acoustic feedback system is open and at least one acoustic feedback system is closed; and a calculating portion configured to calculate a gain correction amount based on the impulse response that the obtaining portion has obtained and to output a calculated gain correction amount.

The signal processing apparatus is configured to reduce both coloration due to the transmission system of an acoustic space and coloration due to signal processing.

The above and other elements, features, characteristics, and advantages of the present invention will become more apparent from the following detailed description of the preferred embodiments with reference to the attached drawings.

### BRIEF DESCRIPTION OF THE DRAWINGS

FIG. 1 is a schematic transparent perspective view of an acoustic space.

FIG. 2 is a block diagram illustrating a configuration of a sound field support (AFC: Active Field Control) system.

FIG. 3 is a block diagram illustrating the AFC system and a Personal Computer (PC).

FIG. 4 is a flow chart showing an operation of a signal processing apparatus.

FIG. 5 is a block diagram illustrating a configuration of the AFC system in an open state.

FIG. 6 is a block diagram illustrating a configuration of the AFC system in a semi-open state.

FIG. 7A and FIG. 7B illustrate an impulse response according to a frequency.

FIG. 8A, FIG. 8B, and FIG. 8C illustrate amplitude correction processing.

FIG. 9A and FIG. 9B are graphs showing frequency characteristics.

FIG. 10 illustrates a comparison between the presence and absence of correction processing.

FIG. 11 is a graph showing a result of quantitative evaluation.

FIG. 12 is a flow chart showing another operation of the signal processing apparatus.

### DETAILED DESCRIPTION OF THE PREFERRED EMBODIMENTS

A signal processing apparatus according to a preferred embodiment of the present invention includes: an obtaining portion configured to obtain an impulse response in a semi-open state in which, among a plurality of acoustic feedback systems, at least one acoustic feedback system is open and at least one acoustic feedback system is closed; and a calculating portion configured to calculate a gain correction amount based on the impulse response that the obtaining portion has obtained and to output a calculated gain correction amount.

Thus, the signal processing apparatus, in order to obtain an impulse response in a semi-open state, may obtain transmission characteristics including an acoustic space and signal processing. Therefore, the signal processing apparatus is able to reduce not only coloration due to the transmission system of an acoustic space but also coloration due to signal processing.

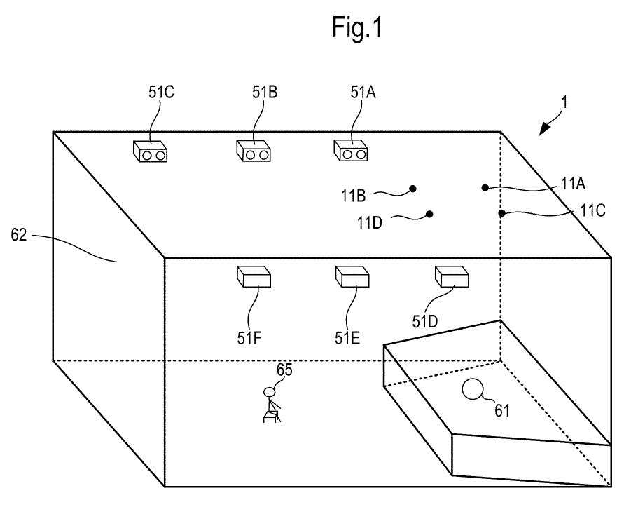

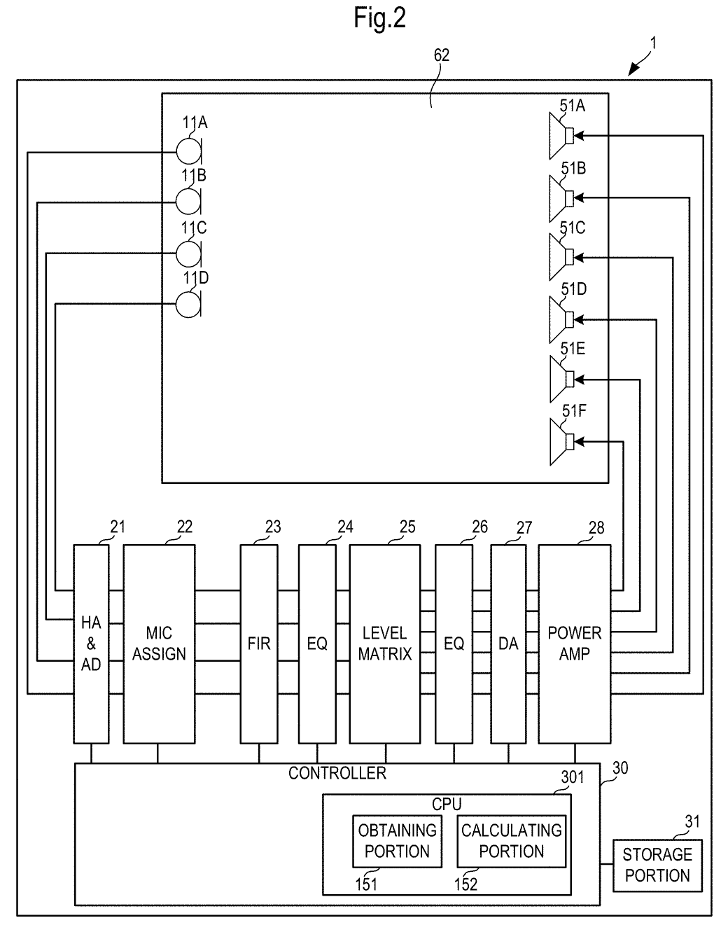

FIG. 1 is a schematic transparent perspective view of an acoustic space. FIG. 2 is a block diagram illustrating a configuration of a sound field support (AFC: Active Field Control) system.

In the acoustic space, a microphone 11A, a microphone 11B, a microphone 11C, a microphone 11D, a speaker 51A, a speaker 51B, a speaker 51C, a speaker 51D, a speaker 51E, and a speaker 51F are installed.

While, in this example, four microphones are installed, the AFC system 1 is able to operate as long as at least one or more microphones are installed. Similarly, the number of speakers is not limited to six, either, and, as long as at least one or more speakers are installed, the AFC system 1 is able to operate.

The microphone 11A, the microphone 11B, the microphone 11C, and the microphone 11D are installed on a ceiling immediately above a sound source 61. The microphone 11A, the microphone 11B, the microphone 11C, and the microphone 11D mainly collect sound that the sound source 61 emits.

The speaker 51A, the speaker 51B, the speaker 51C, the speaker 51D, the speaker 51E, and the speaker 51F are installed in the vicinity of the ceiling immediately above a listener 65. It is to be noted that the installation positions of the microphones and the speakers are not limited to this example.

As illustrated in FIG. 2, the AFC system 1 is provided with a front end circuit (HA&AD) 21, a microphone assigning portion (MIC Assign) 22, an FIR filter 23, an equalizer (EQ) 24, a level matrix (Level Matrix) 25, an EQ 26, a DA converter 27, a power amplifier (Power Amp) 28, a controller 30, and a storage portion 31.

The front end circuit 21 contains a microphone amplifier and an AD converter. The front end circuit 21 amplifies an analog signal that the microphone 11A, the microphone 11B, the microphone 11C, and the microphone 11D have output and outputs the analog signal as a digital signal.

The microphone assigning portion 22 has the function of an EMR (Electronic Microphone Rotator). The EMR is a function to switch with a lapse of time a connection relationship between digital signals of four channels to be input and digital signals of four channels to be output. Accordingly, the microphone assigning portion 22 flattens frequency characteristics of an acoustic feedback system from an acoustic space 62 to the acoustic space 62 back again through a microphone, signal processing, amplification processing, and a speaker.

The FIR filter 23 convolves an impulse response to the digital signals of the four channels to be input and generates a reverberant sound. The storage portion 31 stores data related to the impulse response. The controller 30 reads the data related to a predetermined impulse response from the storage portion 31, and sets a filter coefficient corresponding to the impulse response to the FIR filter 23.

The EQ 24 includes a plurality of parametric equalizers (PEQ), for example. The EQ 24 corrects the gain of a predetermined bandwidth (Q value) around a specified frequency of each of the digital signals of the four channels to be input. The controller 30 specifies a center frequency, a Q value, and a gain.

The level matrix 25 distributes the digital signals of the four channels to be input, to six output channels. The level matrix 25 also performs a gain adjustment and a delay adjustment of each of the output channels. The controller 30 specifies a gain and delay of each of the output channels.

The EQ 26 corrects the frequency characteristics of each of the digital signals of the six channels to be input from the level matrix 25.

The DA converter 27 converts each of the digital signals of the six channels to be output from the EQ 26, to an analog signal.

The power amplifier 28 amplifies each analog signal that has been output from the DA converter 27, and outputs amplified analog signals to the speaker 51A, the speaker 51B, the speaker 51C, the speaker 51D, the speaker 51E, and the speaker 51F, respectively.

The controller 30 reads a program stored in the storage portion 31 and collectively controls the AFC system 1. In the present preferred embodiment, the storage portion 31 may be configured by a volatile memory, a nonvolatile memory, an HDD, an SSD, or the like. The controller 30 implements the functions of the obtaining portion 151 and the calculating portion 152 by causing the CPU 301 to execute the program. In other words, the controller 30 is equivalent to the signal processing apparatus of the present invention, and the CPU 301 is equivalent to the obtaining portion 151 and the calculating portion 152.

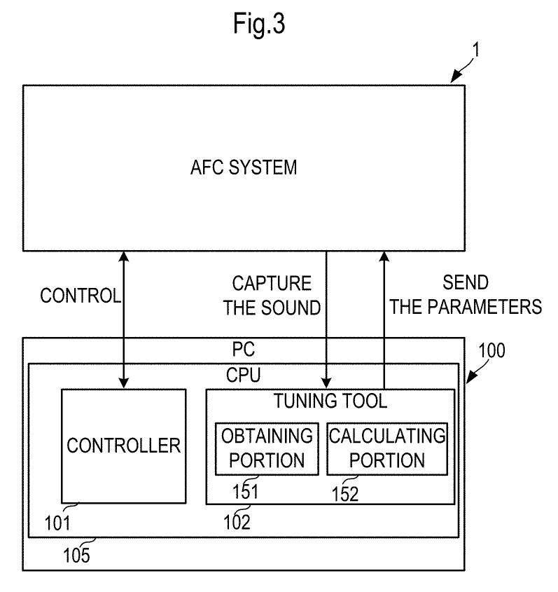

It is to be noted that the function of the controller 30, as illustrated in FIG. 3, is also able to be implemented by an external device (a PC 100 in the present preferred embodiment). In the example of FIG. 3, the PC 100 connected to the AFC system 1 is provided with a controller 101. The controller 101 is implemented when the CPU 105 of the PC 100 executes an application program. The controller 101 controls the various configurations of the AFC system 1. In addition, in this example, the obtaining portion 151 and the calculating portion 152 are implemented as the function of the application program (a tuning tool 102) that the CPU 105 of the PC 100 executes. The tuning tool 102 is equivalent to the signal processing apparatus of the present invention.

The obtaining portion 151 obtains an impulse response to be described later, and the calculating portion 152, based on an obtained impulse response, calculates a parameter (gain correction amount) of the EQ 24 and outputs the parameter to the EQ 24.

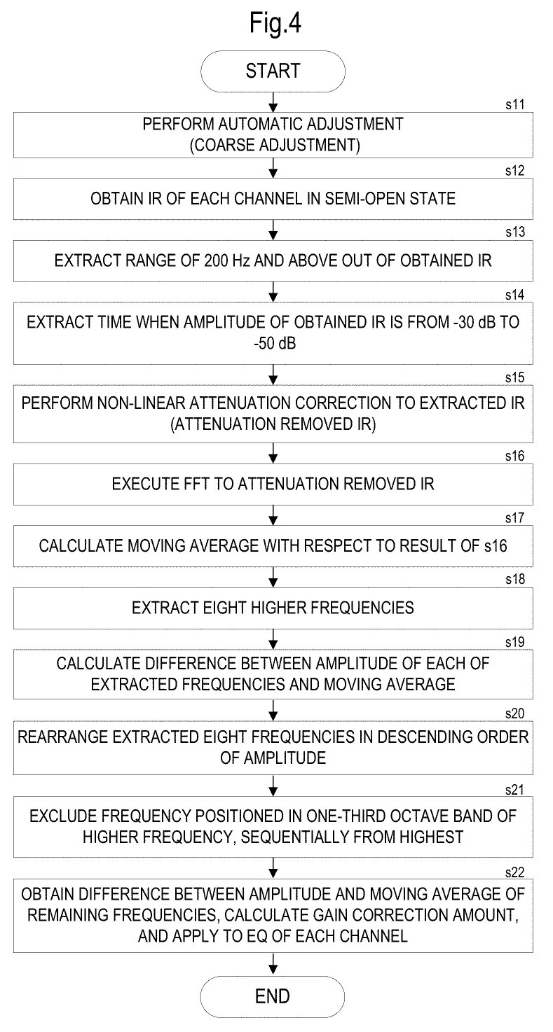

FIG. 4 is a flow chart showing an operation of the AFC system 1. To begin with, the AFC system 1 performs an automatic adjustment (a coarse adjustment) (s11). The coarse adjustment is to perform processing of measuring the impulse response of the acoustic space 62, detecting a frequency at which howling may occur, and reducing the gain of the frequency.

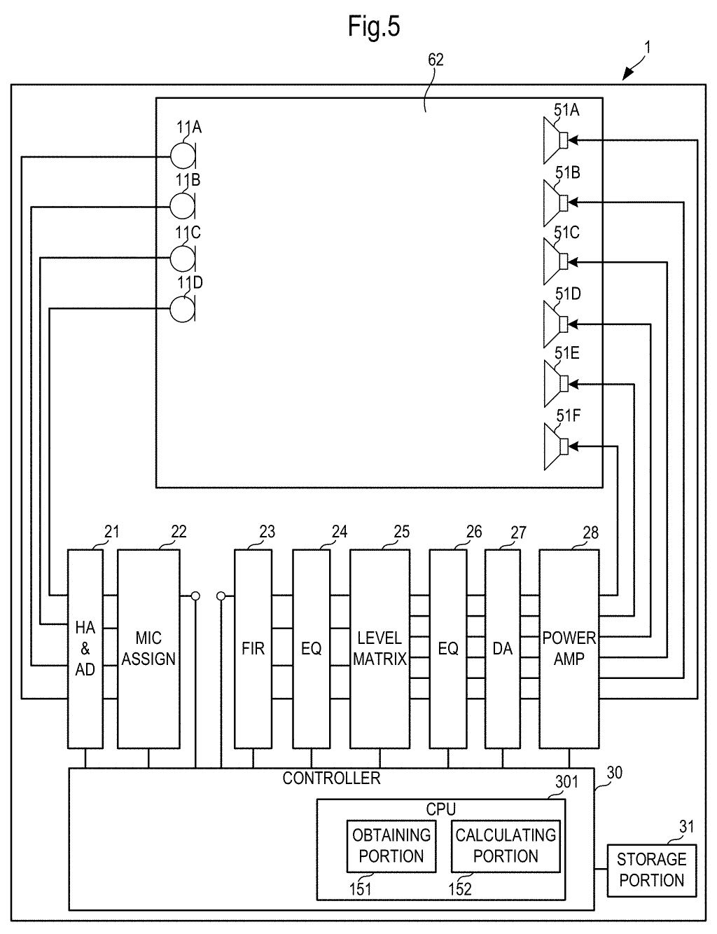

In such a case, as illustrated in FIG. 5, the controller 30 controls the microphone assigning portion 22, stops the output of a signal, and makes an open state. It is to be noted that, while this example illustrates a mode in which the controller 30 controls the microphone assigning portion 22 to make an open state, it is also possible to employ a mode in which the output of a signal in any one of blocks is stopped to make an open state. Moreover, it is also possible to make an open state by installing a switch between any blocks up to the level matrix 25 and turning off the switch.

Then, the controller 30 outputs a measurement sound (impulse sound) to one of the four channels, inputs the measurement sound through a microphone, and obtains an impulse response. The controller 30 converts an obtained impulse response into a frequency signal by a method such as the FFT. The controller 30 detects a frequency of a peak that indicates a remarkably high level on a frequency axis. The controller 30 may detect a frequency that indicates a level equal to or above a predetermined threshold value, for example, as a peak frequency. At the end, the controller 30 sets a center frequency, a Q value, and a gain to the EQ 24 so as to reduce the level of a detected peak frequency.

The controller 30 performs a coarse adjustment by performing the above measurement with respect to all four input channels. Accordingly, the controller 30 reduces howling from occurring, and stabilizes the state of the AFC system 1.

Subsequently, returning to FIG. 4, the controller 30 obtains the impulse response of each channel in a semi-open state (s12).

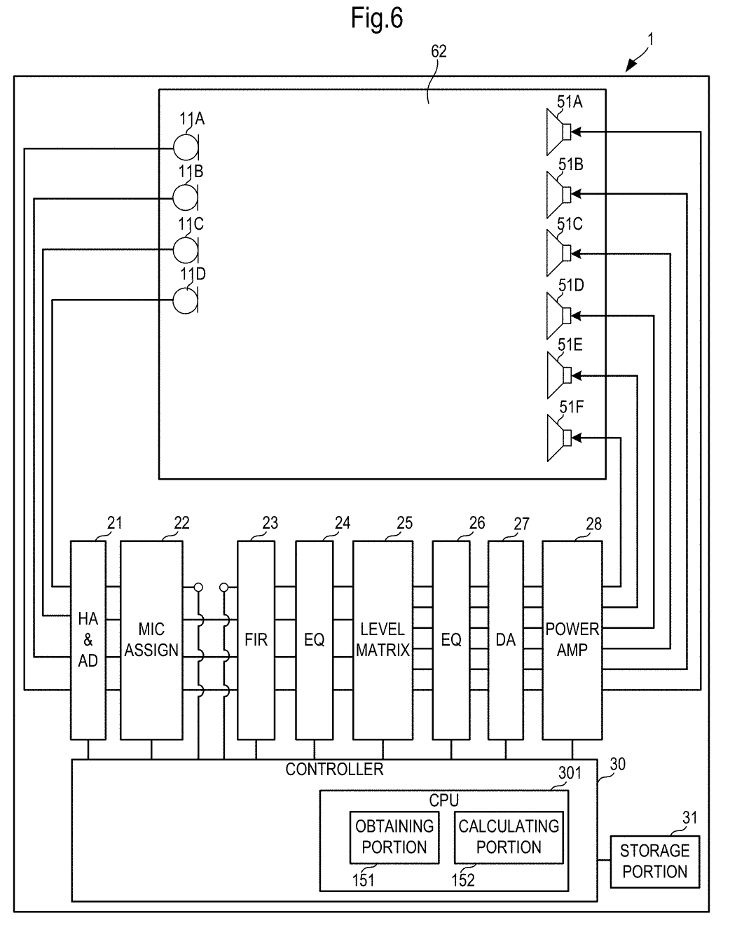

In such a case, as illustrated in FIG. 6, the controller 30 controls the microphone assigning portion 22, opens one channel to be measured, and closes the other channels. It is to be noted that, as described above, the controller 30 may control the microphone assigning portion 22 or the controller 30 may stop the output of a signal in any of the blocks to make a semi-open state. In addition, it is also possible to make a semi-open state by installing a switch between any blocks up to the level matrix 25 and turning on and off the switch.

At this time, the function of the EMR in the microphone assigning portion 22 stops. In other words, the digital signals that have been input from the microphone of each of the channels are respectively output directly in the channels. However, such processing may be performed while the function of the EMR is kept executed.

The controller 30 outputs a measurement sound (impulse sound) to the channel that has been made open, inputs the measurement sound through a microphone, and obtains an impulse response. Thus, the processing of obtaining an impulse response in a semi-open state may be executed by the function of the obtaining portion 151 in the controller 30. On the other hand, the processing at step s13 and the following steps shown in the flow chart of FIG. 4 may be executed by the function of the calculating portion 152 in the controller 30.

Subsequently, the controller 30, with respect to an obtained impulse response, may cut a band below 200 Hz, and may extract a range of 200 Hz and above (s13).

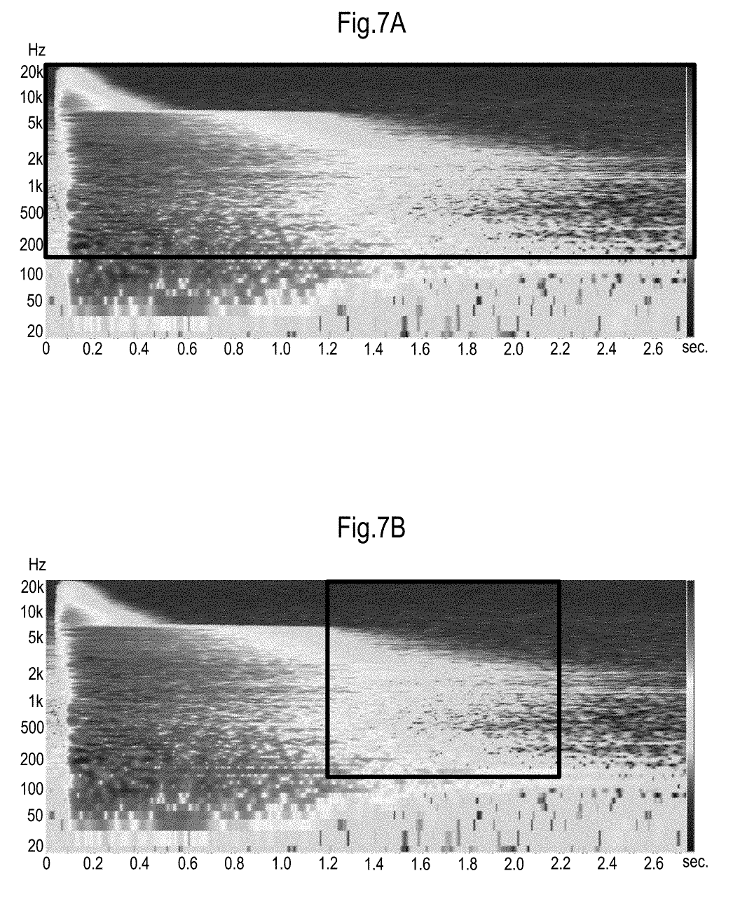

FIG. 7A and FIG. 7B illustrate an impulse response according to a frequency. The vertical axis represents a frequency and the horizontal axis represents time.

As illustrated in FIG. 7A, in the low frequency band, since a level due to background noise in the acoustic space 62 is large, it is difficult to analyze the influence of coloration. Therefore, the controller 30 may perform processing of cutting the band below 200 Hz and extracting the band of 200 Hz and above in which the influence of coloration is large.

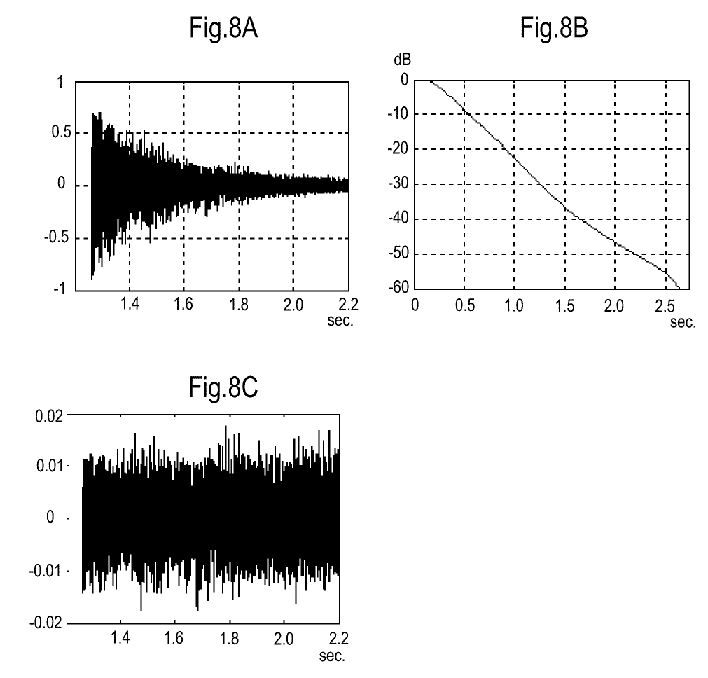

In addition, the controller 30 extracts a predetermined level range (−30 dB to −50 dB, for example) in a reverberation attenuation waveform (see FIG. 8B) calculated from the obtained impulse response (s14). For example, in the example of FIG. 7B, a range from 1.2 sec. to 2.2 sec. corresponds to the range from −30 dB to −50 dB. As illustrated in FIG. 7B, since a high level signal is input for a while after sound is input directly, it is difficult to analyze the influence of coloration. In contrast, when a low level signal is input, the influence of background noise becomes larger. Accordingly, the controller 30, by extracting a time zone in which the level of the obtained impulse response is a predetermined level range (−30 dB to −50 dB, for example), may define a time zone in which the influence of coloration is large, as a processing target.

Subsequently, the controller 30 performs non-linear attenuation correction to an extracted impulse response (s15). The non-linear attenuation correction is to perform processing of raising a gain with a lapse of time so that the level of an impulse response does not attenuate (see Hanyu et al., “Calculation of Attenuation Removed Impulse Response of Indoor Sound Field with Non-Linear Attenuation,” The Acoustical Society of Japan, lecture paper, March 2014).

FIG. 8A illustrates an impulse response (linear scale) that has been cut in a target level range, and FIG. 8B illustrates a reverberation attenuation curve calculated from the impulse response (logarithmic scale). As illustrated in FIG. 8A, the level of the impulse response, on a linear scale, decreases exponentially with a lapse of time. In addition, as illustrated in FIG. 8B, the impulse response, also on a logarithmic scale, changes not with linear attenuation but with a lapse of time.

Accordingly, the controller 30 performs a level adjustment according to attenuation characteristics of the impulse response so that the level of the impulse response may not attenuate. In other words, the controller 30 sets a gain of the inverse characteristics to the attenuation characteristics of the impulse response. In particular, the controller 30 may preferably calculate the attenuation characteristics of the impulse response in each case in a finely divided time range (in a range of 0.5 sec., for example) and obtain a level correction value. For example, at each time in the above mentioned Hanyu method, a short-time attenuation factor is calculated in a section of ±5 dB.

Accordingly, as illustrated in FIG. 8C, the impulse response may be an attenuation removed IR of which the level does not attenuate with a lapse of time.

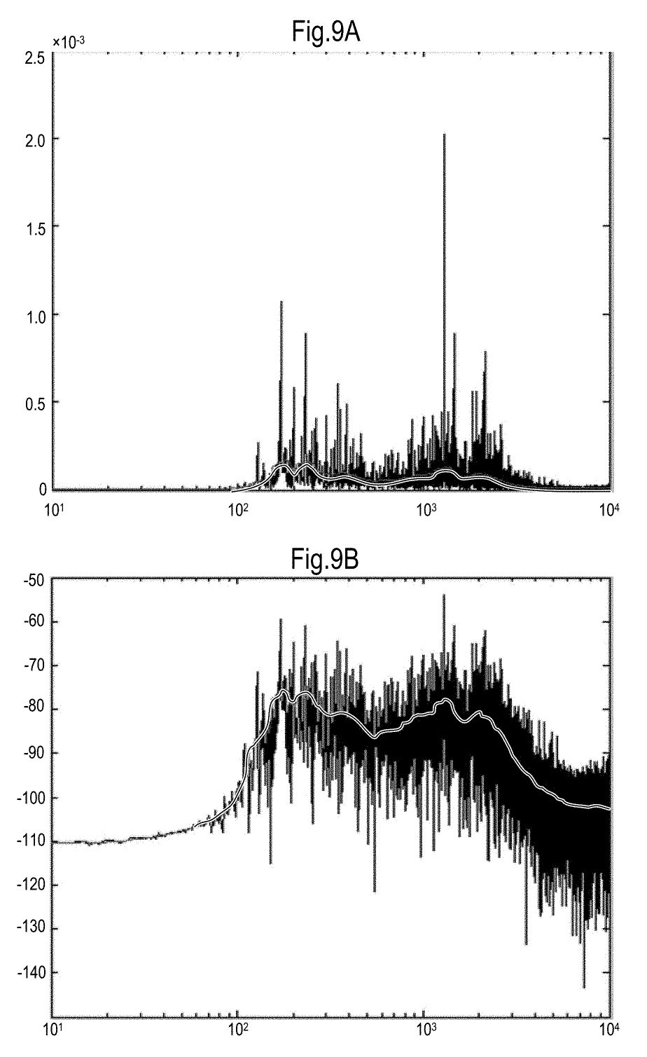

Subsequently, the controller 30 converts a calculated attenuation removed IR into a frequency signal by a method such as the FFT (s16). FIG. 9A is a graph showing the frequency characteristics (linear scale) of an attenuation removed IR, and the characteristics of a moving average, and FIG. 9B is a graph showing the frequency characteristics (logarithmic scale) of an attenuation removed IR, and the characteristics of a moving average.

The controller 30, from the frequency characteristics of the attenuation removed IR as shown in FIG. 9A and FIG. 9B, calculates a target frequency that influences coloration.

The controller 30 may first calculate a moving average, for example, with respect to the frequency characteristics after performing the FFT in the processing of step s16 (s17). The controller 30 calculates an average value of amplitude, for example, while moving a frequency band in the one-third octave width. Any method may be used as long as it can smooth the frequency characteristic of the attenuation removed IR, not limited to the moving average. In addition, the controller 30 extracts a predetermined number (eight in the present preferred embodiment) of peaks sequentially from a peak with the highest amplitude value (s18). Then, the controller 30, with respect to each of the extracted eight peaks, calculates a difference between an amplitude value and a value of the moving average (s19). Subsequently, the controller 30 rearranges the extracted eight peaks in descending order of amplitude (s20). It is to be noted that, the controller 30, in a case in which, sequentially from a peak with the highest amplitude value, a peak of which the level is relatively high is set as a standard and other peaks are in a predetermined band (the one-third octave width, for example) around the frequency of the peak as the standard, may perform processing of excluding the other peaks (s21).

At the end, the controller 30, with respect to the frequency of the peak that has remained after the processing of step s21, obtains a difference between an amplitude value and the above moving average, calculates a gain correction amount, and applies the gain correction amount to a corresponding channel in the EQ 24 (s22). The gain correction amount is set to a value such that the amplitude value of each peak is a moving average value +10 dB, for example. It is to be noted that, while a Q value is arbitrary, the controller 30 sets the greatest Q value that the EQ 24 is able to set, in the present preferred embodiment of the present invention.

With the above processing, in the EQ 24, the gain of the frequency that influences coloration is reduced, so that coloration is able to be reduced. In particular, the controller 30, in order to obtain an impulse response in a semi-open state, performs coloration suppression processing including the signal processing of the AFC system 1.

The controller 30 performs the above processing with respect to each of the four channels and sets a gain correction amount of each of the channels in the EQ 24. It is to be noted that, at the time of actual operation, the EMR functions in the microphone assigning portion 22. Therefore, the controller 30, with respect to all connection configurations by the EMR, may preferably calculate a target frequency of coloration and may preferably calculate a gain correction amount. In addition, as described above, the controller 30, in a state in which the function of the EMR in the microphone assigning portion 22 is executed, may obtain an impulse response.

Moreover, while, in the above example, a mode in a semi-open state in which a channel to be analyzed is open and all the other channels are closed is described, the controller 30 may perform various types of processing in a semi-open state in which at least one acoustic feedback system (channel to be analyzed) is open and at least one acoustic feedback system is closed.

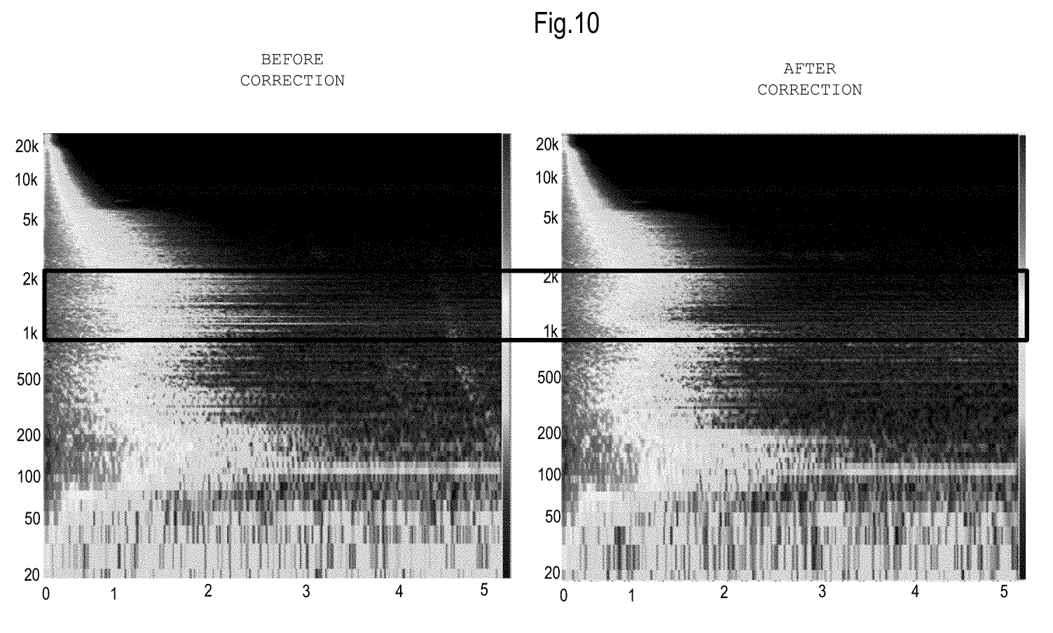

Subsequently, FIG. 10 illustrates a comparison between the presence and absence of correction processing (illustrates an impulse response according to a frequency). As illustrated in FIG. 10, the impulse response before correction has a portion that does not attenuate in some frequencies even after several seconds pass. The frequency components that do not attenuate may be coloration. However, in the impulse response after correction, the frequency components are reduced. Thus, coloration is reduced by correction processing.

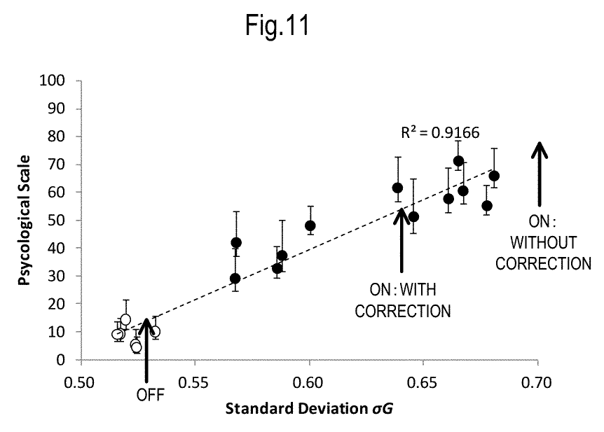

In addition, FIG. 11 is a graph showing a result of the quantitative evaluation of coloration. The horizontal axis of the graph represents the standard deviation of frequency characteristics. As a frequency component that represents a high level peak increases, the standard deviation becomes larger. The vertical axis of the graph represents a psychological scale and corresponds to the percentage of people who feel coloration.

As shown in FIG. 11, the standard deviation has a high correlation with the occurrence of coloration. In other words, the graph of FIG. 11 shows that coloration is reduced as the standard deviation decreases. The “OFF” in FIG. 11 indicates a state in which the AFC system 1 is not in operation. In a case in which the AFC system 1 is not in operation, only a natural reverberant sound in the acoustic space 62 occurs without an acoustic feedback system, so that people who feel coloration are extremely small. On the other hand, the “ON: WITHOUT CORRECTION” on the right side of FIG. 11 indicates a state in which the AFC system 1 is operated after the coarse adjustment shown at step s11 of FIG. 4 is performed. When the AFC system 1 is operated, an acoustic feedback system is formed, so that the standard deviation becomes larger and the percentage of people who feel coloration increases. However, as shown in the “ON: WITH CORRECTION” in FIG. 11, if the various types of processing at step s12 and the following steps shown in the present preferred embodiment are performed, the standard deviation becomes smaller and the percentage of people who feel coloration decreases.

Therefore, the controller 30, by obtaining an impulse response in a semi-open state and calculating a gain correction amount based on an obtained impulse response, is able to reduce both coloration due to the transmission system of an acoustic space and coloration due to signal processing.

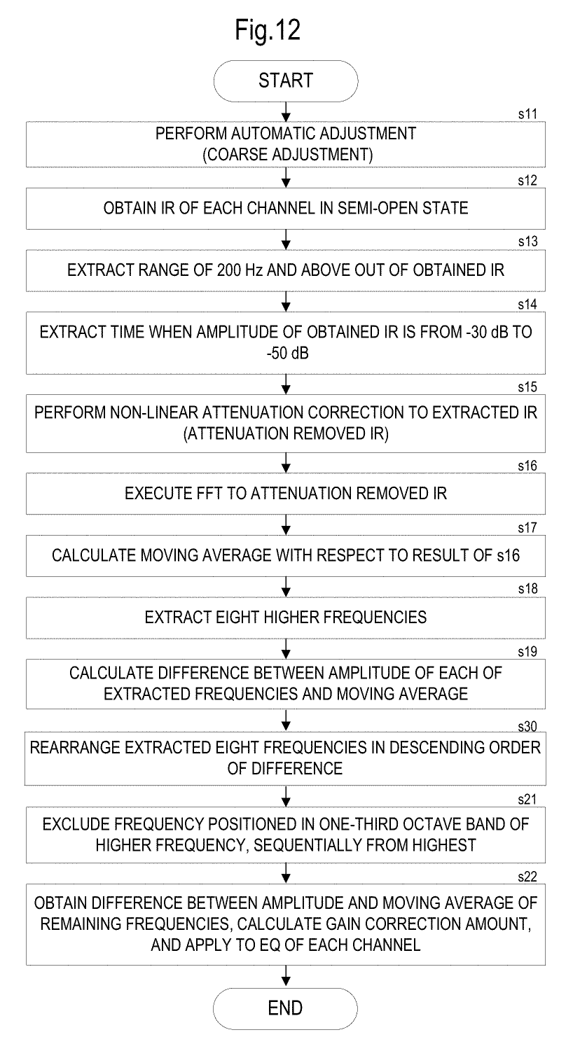

Subsequently, FIG. 12 is a flow chart showing an operation of the controller 30 according to a modification. Like reference numerals are used to indicate processing common to the processing shown in FIG. 4, and the associated description will be appropriately omitted.

In the modification, the controller 30 rearranges extracted eight peaks, in descending order of the difference calculated at step s19 (s30). In other words, in the modification, priority is given not to the size of the amplitude value of each peak but to a large difference with a moving average. Accordingly, the controller 30 is able to perform more natural correction by hearing.

It is to be noted that, while an example in which a high level peak frequency is set to be a target frequency of coloration is shown in the present preferred embodiment, a method of extracting the target frequency of coloration is not limited to this example. For example, with respect to an obtained impulse response, power for each predetermined frequency band (one-third octave width, for example) is measured, and, when measured power exceeds a predetermined threshold value, processing of reducing the frequency band may be performed. In addition, a frequency of which the difference with a moving average is smaller than a predetermined value may be specified and another frequency other than the frequency may be set as a target frequency of coloration.

Finally, the foregoing preferred embodiments are illustrative in all points and should not be construed to limit the present invention. The scope of the present invention is defined not by the foregoing preferred embodiment but by the following claims. Further, the scope of the present invention is intended to include all modifications within the scopes of the claims and within the meanings and scopes of equivalents.

What is claimed is:

1. A signal processing apparatus comprising:
an obtaining portion configured to obtain an impulse response in a semi-open state in which, among a plurality of acoustic feedback systems, at least one acoustic feedback system is open and at least one acoustic feedback system is closed; and
a calculating portion configured to calculate a gain correction amount based on the impulse response that the obtaining portion has obtained and to output a calculated gain correction amount.

2. The signal processing apparatus according to claim 1, wherein the calculating portion is configured to calculate a target frequency of coloration and calculate the gain correction amount so as to reduce a gain of the target frequency.

3. The signal processing apparatus according to claim 2, wherein the calculating portion is configured to set a frequency that shows one or more peaks to the target frequency.

4. The signal processing apparatus according to claim 3, wherein
the one or more peaks include a first peak of which a level is relatively large, and a second peak; and
the calculating portion, when calculating the target frequency, excludes the second peak in a case in which the first peak is set as a standard and a frequency of the second peak is in a predetermined band around a frequency of the first peak.

5. The signal processing apparatus according to claim 3, wherein
the calculating portion is configured to calculate a difference between a moving average on a frequency axis of the impulse response and each of the one or more peaks; and
the calculating portion, when calculating the target frequency, in a case in which, among the one or more peaks, a first peak corresponding to a relatively large difference is set as a standard and a frequency of a second peak is in a predetermined band around a frequency of the first peak, excludes the second peak.

6. The signal processing apparatus according to claim 1, wherein the calculating portion is configured to extract a predetermined frequency band out of frequency characteristics of the impulse response.

7. The signal processing apparatus according to claim 1, wherein the calculating portion is configured to extract a time zone as a predetermined level range, out of the impulse response.

8. The signal processing apparatus according to claim 1, wherein the calculating portion is configured to perform level correction according to attenuation characteristics, with respect to the impulse response.

9. The signal processing apparatus according to claim 1, wherein the calculating portion is configured to calculate a moving average on a frequency axis of the impulse response and calculate the gain correction amount based on a level of the impulse response and a level of the moving average.

10. A signal processing method comprising:
obtaining an impulse response in a semi-open state in which, among a plurality of acoustic feedback systems, at least one acoustic feedback system is open and at least one acoustic feedback system is closed; and
calculating a gain correction amount based on an obtained impulse response and outputting a calculated gain correction amount.
